(19) United States
(12) Patent Application Publication
(10) Pub. No.: US 2026/0147246 A1
(43) Pub. Date: May 28, 2026

(54) DISPLAY DEVICE

(71) Applicant: LG Display Co., Ltd., Seoul (KR)

(72) Inventors: Jinhyung Jung, Goyang-si (KR); TaeWoon Ko, Seoul (KR)

(73) Assignee: LG Display Co., Ltd., Seoul (KR)

(21) Appl. No.: 19/334,672

(22) Filed: Sep. 19, 2025

(30) Foreign Application Priority Data
Nov. 28, 2024 (KR) 10-2024-0173519

(51) Int. Cl. G02F 1/1345; G02F 1/13357; G02F 1/1368; H10D 86/40; H10D 86/60

(52) U.S. Cl. CPC G02F 1/13458; G02F 1/1336; G02F 1/1368; H10D 86/441; H10D 86/60

(57) ABSTRACT

A display device includes a lower substrate having a thin film transistor disposed thereon, an upper substrate disposed above the lower substrate, a plurality of pad electrodes disposed in a non-active area of the lower substrate, a hole extending through the lower substrate from a lower surface of the lower substrate toward a pad electrode, among the plurality of pad electrodes, and a flexible film coupled to the pad electrode through a conductive layer disposed in the hole. Accordingly, the width of the front edge is minimized or reduced without flipping the substrate so that the increase in the reflectance of the display panel and the degradation of the rigidity of the display unit due to the flipping of the substrate may be suppressed.

### CROSS-REFERENCE TO RELATED APPLICATION

This application claims the priority of Korean Patent Application No. 10-2024-0173519, filed on Nov. 28, 2024, in the Korean Intellectual Property Office, the disclosure of which is incorporated herein by reference.

### BACKGROUND

### Field

The present disclosure relates to a display device and, more particularly, to a display device with a reduced bezel (narrow bezel) structure.

### Description of the Related Art

Currently, as we enter a full-scale information era, a field of a display device which visually expresses electrical information signals has been rapidly developed, and studies are continuing to improve performances of various display devices, such as a thinner profile, a lighter weight, and lower power consumption.

As representative display devices, there are a liquid crystal display device (LCD), an electro-wetting display device (EWD), and an organic light emitting display device (OLED).

The liquid crystal display device includes a liquid crystal display panel in which an upper substrate and a lower substrate are bonded with a liquid crystal layer interposed therebetween, a driving circuit which applies a predetermined driving signal to a liquid crystal display panel, and an assembly component which assembles the liquid crystal display panel and the driving circuit and may further include various components according to an application field, such as a computer monitor or a television.

### SUMMARY

An object of the present disclosure is to provide a display device which minimizes or reduces a width of a front edge and also reduces a reflectance of the display panel.

Another object of the present disclosure is to provide a display device which minimizes or reduces a width of the front edge and also suppresses degradation of a strength of the display unit.

Objects of the present disclosure are not limited to the above-mentioned objects, and other objects, which are not mentioned above, can be clearly understood by those skilled in the art from the following descriptions.

To achieve the above-described and other objects, according to an aspect of the present disclosure, a display device may include a lower substrate having a thin film transistor disposed thereon, an upper substrate disposed above the lower substrate, a plurality of pad electrodes disposed in a non-active area of the lower substrate, a hole extending through the lower substrate from a lower surface of the lower substrate toward a pad electrode, among the plurality of pad electrodes, and a flexible film coupled to the pad electrode through a conductive layer disposed in the hole.

According to another aspect of the present disclosure, a display device includes a lower substrate having a thin film transistor disposed thereon, an upper substrate disposed above the lower substrate, a plurality of wiring lines disposed in an active area of the lower substrate and applying a signal or a voltage to the thin film transistor, a plurality of pad electrodes disposed in a pad area of the lower substrate and is electrically coupled to the plurality of wiring lines, a plurality of holes extending through the lower substrate from a lower surface of the lower substrate toward the plurality of pad electrodes, respectively, and a flexible film coupled to a pad electrode, among the plurality of pad electrodes, through a conductive layer disposed in a corresponding one of the plurality of holes. The flexible film is disposed on a rear surface of the lower substrate so as not to be visible from an upper portion of the lower substrate.

Other detailed matters of various example embodiments are included in the detailed description and the drawings.

According to example embodiments of the present disclosure, a hole is formed in a lower array substrate to couple a pad unit and a flexible film, thereby minimizing or reducing a width of the front edge without flipping the substrate. As a result, an overall thickness of the display device is reduced to implement a slim design and also implement a slim and simple design.

Further, according to example embodiments of the present disclosure, the width of the front edge is minimized or reduced without flipping the substrate so that the increase in the reflectance of the display panel and the degradation of the strength of the display unit due to the flipping of the substrate can be suppressed. Accordingly, the aesthetics of the display device may be improved and a significant effect on maintaining the durability and performance of the display device may be achieved. When the strength of the display unit is degraded, damage or breakage may easily occur so that, if the degradation of the strength is suppressed, the entire lifespan of the display device may be extended. Further, the failure and the need for repairs due to the degradation of the strength of the display unit are reduced, resulting in savings in maintenance costs.

The effects according to the present disclosure are not limited to the contents exemplified above, and various additional effects may be attained from the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a front view of a display device according to an example embodiment of the present disclosure;

FIG. 2 is a rear view of a display unit according to an example embodiment of the present disclosure;

FIG. 3 is a cross-sectional view taken along line I-I′ in FIG. 1;

FIG. 4 is a cross-sectional view of a display unit according to a comparative example;

FIG. 5 is a perspective view illustrating a part of a side surface of the display device of FIG. 3;

FIG. 6 is a plan view illustrating a part of a display panel according to an example embodiment of the present disclosure;

FIG. 7 is a cross-sectional view illustrating a part of a display panel according to an example embodiment of the present disclosure;

FIG. 8 is a plan view illustrating a part of a display panel according to another example embodiment of the present disclosure; and

FIG. 9 is a cross-sectional view illustrating a part of a display panel according to another example embodiment of the present disclosure.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein and may be implemented in various other forms. The example embodiments are provided by way of example only so that those skilled in the art can more fully understand the features and aspects of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. Such terms as “including,” “having,” and “consist of,” where used herein, are generally intended to allow other components to be added unless the terms are used with a more limiting term like “only”. Any references to singular may include plural, and vice versa, unless expressly stated otherwise.

Components are to be interpreted to include an ordinary error range even if not expressly stated.

Where the position relation between two parts is described using such terms as “on”, “above”, “below”, and “next”, one or more parts may be positioned between the two parts unless the terms are used with a more limiting term like “immediately” or “directly”.

Where an element or layer is described as being disposed “on” another element or layer, the element or layer may be disposed directly on the other element or layer, or an additional layer or element may be interposed directly on the other element or therebetween.

Although the terms “first”, “second”, and the like may be used for describing various components, these components are not confined by these terms. These terms are merely used to refer to one component separately from the other components. Therefore, a first component to be mentioned below may be a second component, and vice versa, in a technical concept of the present disclosure.

Like reference numerals generally denote like elements throughout the specification unless otherwise specified.

A size and a thickness of each component illustrated in the drawing are illustrated for convenience of description, and the present disclosure is not limited to the size and the thickness of the component illustrated.

The features of various example embodiments of the present disclosure can be partially or entirely adhered to or combined with each other and can be interlocked and operated in technically various ways, and the example embodiments can be carried out independently of or in association with each other.

Hereinafter, example embodiments of the present disclosure will be described in detail with reference to the drawings.

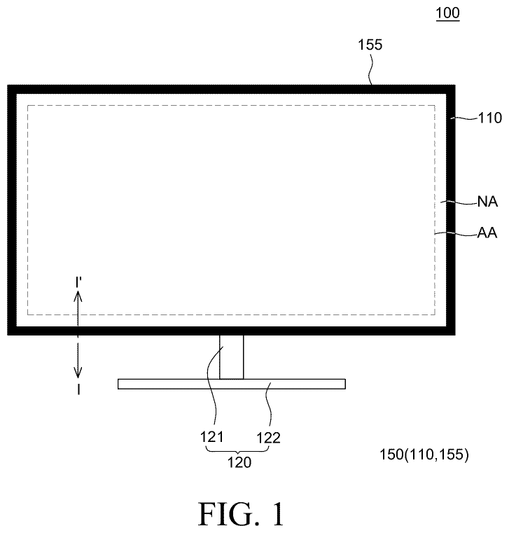

FIG. 1 is a front view of a display device according to an example embodiment of the present disclosure.

FIG. 1 illustrates a display device with a stand fixing structure as an example, but the present disclosure is not limited thereto and may also be applied to a mobile display device, such as a smart phone or a free-standing display which is attached to a separate device or a wall without a fixed stand or is used to be connected to an independent stand.

As shown in FIG. 1, a display device 100 according to an example embodiment of the present disclosure includes a display panel 110 which displays an image and a stand unit 120 which is installed below the display panel 110 to support a load of the display panel 110 and configures one set.

The display device 100 having a stand fixing structure is used as a stand structure to be equipped on a bottom surface of a predetermined space, such as a computer monitor or a television.

The display device 100 according to the example embodiment of the present disclosure further includes a cover unit which fixes or covers the display panel 110 and for the convenience of description, the display panel 110 and the cover unit are referred to as a display unit 150.

At this time, the cover unit includes a bottom cover 155 which encloses a rear surface and a side surface of the display panel 110 and a guide panel (not illustrated). The cover unit further includes a top case which encloses the display panel 110 along the front edge of the display panel 110 to be coupled to a side surface of the guide panel. In the present disclosure, to implement a narrow bezel, a top case is omitted.

The display panel 110 is a panel for displaying images to a user.

The display panel 110 includes an active area AA and a non-active area NA.

The active area AA is an area where images are displayed in the display panel 110.

In the display panel 110, a display element which displays images, a driving element which drives the display element, and wiring lines which transmit various signals to the display element and the driving element are disposed. The plurality of sub pixels is minimum units which configure the active area AA, and a display element may be disposed in each of the plurality of sub pixels. The plurality of sub pixels may configure a pixel. The display element may be defined in various manners depending on the type of the display panel 110 and for example, when the display panel 110 is a liquid crystal display panel, the display panel 110 may be configured to include an upper substrate and a lower substrate and a liquid crystal layer interposed between the upper substrate and the lower substrate. For example, in each of the plurality of sub pixels, a thin film transistor which is a switching element may be disposed, but is not limited thereto. Further, a circuit for driving the plurality of sub pixels may include a driving element and a wiring line. For example, the circuit may be configured by a thin film transistor, a storage capacitor, a gate line, and a data line, but is not limited thereto.

Hereinafter, it is assumed that the display panel 110 is a liquid crystal display panel, but the present disclosure is not limited thereto. For example, when the display panel 110 is an organic light emitting display panel, the display element may be an organic light emitting diode.

The non-active area NA is an area where no image is displayed.

Even though in FIG. 1, it is illustrated that the non-active area NA encloses a quadrangular active area AA, shapes and placements of the active area AA and the non-active area NA are not limited to the example illustrated in FIG. 1. That is, the active area AA and the non-active area NA may have shapes suitable for a design of an electronic device including the display device. Another example shape of the active area AA may be a pentagon, a hexagon, a circle, or an oval.

In the non-active area NA, various wiring lines and circuits for driving the liquid crystal display element of the active area AA are disposed. For example, in the non-active area NA, a wiring line which transmits signals to the plurality of sub pixels and circuits of the active area AA or a driving IC such as a gate driver IC or a data driver IC may be disposed, but it is not limited thereto.

As described above, the display panel 110 is configured by the upper substrate, the lower substrate, and the liquid crystal layer between the upper substrate and the lower substrate. The liquid crystal display device is a flat panel display device which displays an image by adjusting a transmittance of light in accordance with alignment of liquid crystal molecules of the liquid crystal layer when light transmits.

Further, a backlight unit which supplies light and a bottom cover 155 in which the backlight unit and the display panel 110 are accommodated may be disposed below the display panel 110.

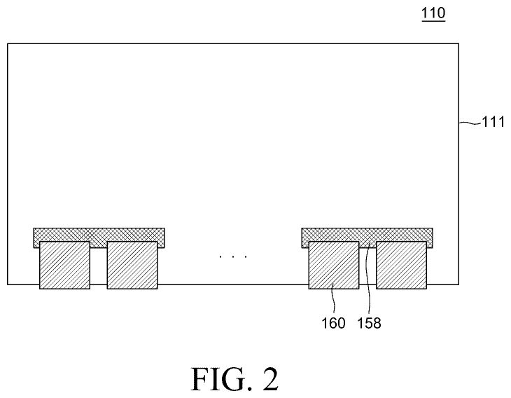

For example, the backlight unit includes a light source and an optical unit which supplies light generated from the light source to the display panel 110. Some components of the bottom cover 155 and the backlight unit are fixed by the guide panel disposed below the display panel 110. The display panel 110 will be described below in more detail with reference to FIGS. 2 to 4.

In the meantime, the stand unit 120 supports the display unit 150 to stand upright on a flat table.

For example, the stand unit 120 includes a fixing plate which includes a plurality of through holes to be fastened to a rear surface of the bottom cover 155 through a screw coupled to the rear surface of the bottom cover 155 and a tilt adjusting unit which is integrally formed with the fixing plate to adjust a vertical angle (tilt) of the display unit 150. At this time, the stand unit 120 is configured by a support unit 121 which is coupled to the tilt adjusting unit to support the display unit 150 and a base plate 122 which is provided on a bottom surface of the support unit 121 to support a load of the display unit 150.

In the meantime, according to the example embodiment of the present disclosure, the pad unit and the flexible film are coupled by forming a hole in the lower array substrate of the display panel so that the top case or the front cover is removed and a width of the front edge of the bottom cover 155 may be minimized or reduced. Accordingly, an overall thickness of the display device is reduced to implement a slim design. Further, according to the present disclosure, the width of the front edge is minimized or reduced without flipping the substrate so that the increase in the reflectance of the display panel and the degradation of the strength of the display unit 150 due to the flipping of the substrate may be suppressed.

FIG. 2 is a rear view of a display panel according to an example embodiment of the present disclosure.

As shown in FIG. 2, the flexible film 160 and a source printed circuit board 158 are disposed on a rear surface of the display panel 110.

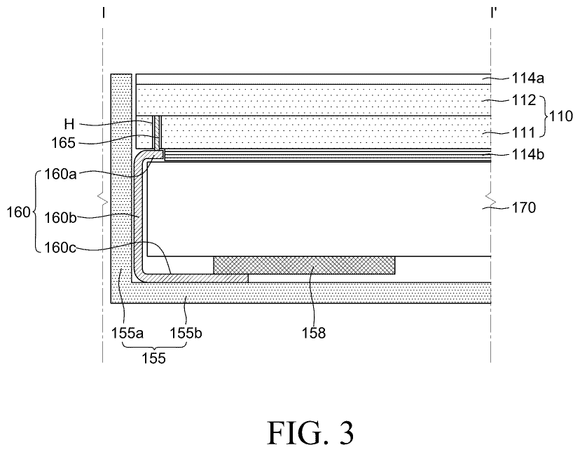

According to the example embodiment of the present disclosure, an upper color filter structure in which an upper substrate 112 (shown in FIG. 3) which is a color filter substrate is located above the lower substrate 111 which is an array substrate is provided.

Further, according to the example embodiment of the present disclosure, the pad unit and the flexible film 160 are coupled by forming the hole in the lower substrate 111 so that the width of the front edge is minimized or reduced without flipping the substrate, which will be described in detail through the following cross-sectional structure.

FIG. 3 is a cross-sectional view taken along I-I′ of FIG. 1.

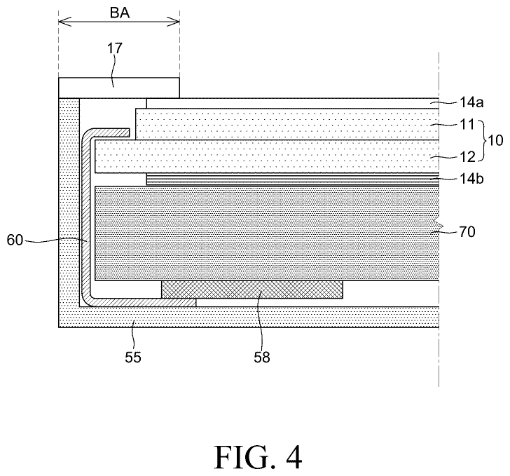

FIG. 4 is a cross-sectional view of a display unit according to a comparative embodiment.

In FIGS. 3 and 4, for the sake of convenience, a specific configuration of the backlight units 170 and 70 is not illustrated.

As shown in FIG. 3, a display unit (150 in FIG. 1) of the example embodiment of the present disclosure includes a display panel 110 which displays images, a backlight unit 170 which is disposed on a rear surface of the display panel 110, and a bottom cover 155 which is disposed on a rear surface of the backlight unit 170. The bottom cover 155 encloses side surfaces of the display panel 110 and the backlight unit 170.

First, the display panel 110 is configured by upper and lower substrates 112 and 111 and a liquid crystal layer (not illustrated) filled between the upper and lower substrates 112 and 111.

Hereinafter, it is assumed that the display panel 110 is a liquid crystal display panel, but as described above, the present disclosure is not limited thereto. When the display panel 110 is an organic light emitting display panel, the display element may be an organic light emitting diode.

Upper and lower polarizers 114a and 114b which selectively transmit only specific light may be attached on outsides of the upper and lower substrates 112 and 111.

In the meantime, the display panel 110 according to the example embodiment of the present disclosure, for example, may have a structure in which the upper substrate 112 which is a color filter substrate is located above the lower substrate 111 which is an array substrate. Further, for example, the lower substrate 111 and the upper substrate 112 may have the same size. However, the present disclosure is not limited thereto and the array substrate is located above the color filter substrate and the lower substrate 111 and the upper substrate 112 may have different sizes.

As shown in FIG. 4, the comparative embodiment having a color filter substrate top-structure in which the color filter substrate 11 of the display panel 10 is located above the array substrate 12 is illustrated.

Unlike the example embodiment of the present disclosure, in the comparative embodiment, the upper polarizer 14a is attached to the outside of the color filter substrate 11 and the lower polarizer 14b is attached to the outside of the array substrate 12.

The backlight unit 70 is disposed below the display panel 10 configured as described above and the bottom cover 55 which accommodates the backlight unit 70 and the display panel 10 is disposed below the backlight unit 70. Further, the source printed circuit board 58 is disposed below the backlight unit 70.

In the meantime, in the comparative example of FIG. 4, one side of the array substrate 12 protrudes from the color filter substrate 11 due to the pad unit for connection of the flexible film 60. In this case, a tool, such as a front cover 17, covers the pad unit and the flexible film 60 connected to the pad unit, and the width BA of the front edge is increased to degrade the aesthetics.

Therefore, an array substrate top-structure in which the array substrate is located above the color filter substrate may be applied. In this case, four-side borderless design may be implemented. That is, the pad unit is located on the rear surface of the array substrate in the viewing direction to be covered so that a tool for covering the pad unit is not necessary so that it is advantageous in that the width of the front edge may be minimized or reduced. However, a display quality may be degraded due to the reflection by an electrode or a wiring line configured on the array substrate. Further, as the fragile array substrate surface is exposed to the outside due to the inorganic material deposition process, it becomes more vulnerable to external impact and may be easily broken.

As shown in FIG. 3 again, according to the present disclosure, in the color filter substrate top-structure, the hole H is formed in the lower substrate 111 to couple the pad unit and the flexible film 160 so that the width of the front edge may be minimized or reduced without flipping the substrate. As a result, the overall thickness of the display device 100 is reduced to implement a slim four-sided borderless design. Further, the sizes of the lower substrate 111 and the upper substrate 112 are equal so that four-side design of the upper substrate 112 is formed in the same way to improve aesthetics. For example, a bezel width below the display panel 110 to which the flexible film 160 is coupled is reduced by approximately 50% as compared with the comparative embodiment.

Further, according to the present disclosure, the width of the front edge is minimized or reduced without flipping the substrate so that the increase in the reflectance of the display panel 110 and the degradation of the strength of the display unit 150 due to the flipping of the substrate may be suppressed. That is, reflection by the electrode or wiring line configured on the lower substrate 111 is blocked by the color filter and the black matrix configured on the upper substrate 112 and a surface of the upper substrate 112 is exposed to the outside so that the existing rigidity may be maintained.

For example, the reflectance of the display panel 110 may be reduced by approximately 40% as compared with the array substrate top-structure. Further, in the ball drop test, the reflectance is improved by three times or more as compared with the array substrate top-structure. Accordingly, the aesthetics of the display device 100 is improved and the durability and the performance of the display device 100 may be effectively maintained. When the strength of the display unit 150 is degraded, damage or breakage may easily occur so that the entire lifespan of the display device 100 may be extended by suppressing the degradation of the strength. Further, the failure and the need for repairs due to the degradation of the strength of the display unit 150 are reduced to save the maintenance cost.

In the meantime, the flexible film 160 is a film in which various components are disposed on a base film having a ductility. Specifically, the flexible film 160 is a film which supplies a signal to the plurality of sub pixels and the circuits of the active area AA and is electrically coupled to the pad unit of the lower substrate 111 through the hole H. Specifically, a hole H which passes through the lower substrate 111 is formed from the rear surface of the lower substrate 111 to the pad unit and the flexible film 160 and the pad unit of the lower substrate 111 are electrically coupled through a conductive layer 165 in the hole H.

For example, the flexible film 160 includes a first coupling unit 160a, a connection unit 160b, and a second coupling unit 160c. The first coupling unit 160a is disposed on the rear surface of the lower substrate 111 to be coupled to the pad unit of the lower substrate 111 through the conductive layer 165 in the hole H. The connection unit 160b extends from the first coupling unit 160a to be bent toward a side surface of the backlight unit 170. The second coupling unit 160c is bent toward a rear surface of the backlight unit 170 from the connection unit 160b to be electrically coupled to the source printed circuit board 158.

As described above, the flexible film 160 is disposed on a rear edge of the display panel 110 so that it is not exposed to the outside. Therefore, there is no need to provide a tool for covering the flexible film so that the width of the front edge may be minimized or reduced.

Further, the flexible film 160 supplies a power voltage or a data voltage to the plurality of sub pixels and circuits of the active area AA. In the meantime, the number of flexible films 160 may vary depending on the design, and is not limited thereto.

For example, a driving IC such as a data driver IC may be disposed on the flexible film 160. The driving IC is a component which processes a data signal for displaying images and a driving signal for processing the data signal. The driving IC may be disposed by a chip on glass (COG), a chip on film (COF), or a tape carrier package (TCP) depending on a mounting method.

Further, the source printed circuit board 158 is disposed on one end of the flexible film 160 to be electrically coupled to the second coupling unit 160c of the flexible film 160. The source printed circuit board 158 is a component which supplies signals to the driving IC. The source printed circuit board 158 supplies various signals such as a driving signal or a data signal to the driving IC. For example, a data driver which generates data signals may be mounted in the source printed circuit board 158 and the generated data signal may be supplied to the plurality of sub pixels and the circuit of the display panel 110 through the flexible film 160. The number of source printed circuit boards 158 may vary depending on the design, and is not limited thereto.

In the meantime, a backlight unit 170 which supplies light, a bottom cover 155 which accommodates the backlight unit 170 and the display panel 110, and a guide panel are disposed on the rear surface of the display panel 110 configured as described above.

The bottom cover 155 of the example embodiment of the present disclosure may accommodate the display panel 110 and the backlight unit 170. To this end, the bottom cover 155 of the example embodiment of the present disclosure is configured by a lower portion 155b which is disposed on the rear surface of the backlight unit 170 to support the backlight unit 170 and a side portion 155a which is vertically bent from the edge of the lower portion 155b. The side portion 155a of the bottom cover 155 may be bent in an “L” shape to accommodate the backlight unit 170.

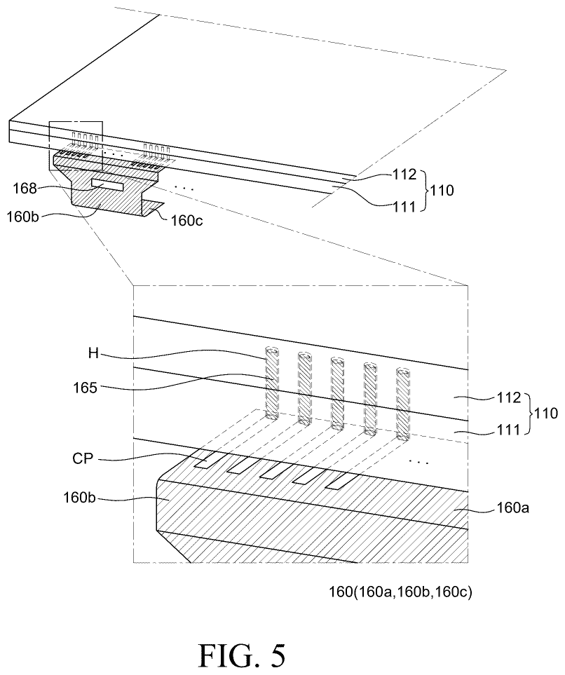

FIG. 5 is a perspective view illustrating a part of a side surface the display device of FIG. 3.

As shown in FIG. 5, according to the example embodiment of the present disclosure, in a state in which the upper substrate 112 is located above the lower substrate 111, a hole H is formed in the lower substrate 111 to couple the pad unit and the flexible film 160, thereby minimizing or reducing the width of the front edge without flipping the substrate.

To this end, a plurality of hole H which exposes the pad electrode of the pad unit is provided in the lower substrate 111.

The hole H may pass through the lower substrate 111 from the rear surface of the lower substrate 111 to the pad unit.

For example, a cross-sectional shape of the hole H is a circle, but is not limited thereto and may be various shapes, such as an oval or a polygon.

The number of holes H may correspond to the number of pad electrodes of the pad unit.

The holes H may be provided so as to correspond to the pad electrodes of the pad unit one to one.

The conductive layer 165 is disposed in the hole H.

The conductive layer 165 may be printed using metal, such as copper (Cu), but is not limited thereto.

Upper and lower portions of the hole H may be electrically conducted by the conductive layer 165.

One end of the conductive layer 165 is electrically coupled to the pad electrode of the pad unit and the other end is electrically coupled to the first coupling unit 160a of the flexible film 160.

For example, the flexible film 160 includes a first coupling unit 160a, a connection unit 160b, and a second coupling unit 160c. The first coupling unit 160a is disposed on the rear surface of the lower substrate 111 to be coupled to the pad unit of the lower substrate 111 through the conductive layer 165 in the hole H. The connection unit 160b extends from the first coupling unit 160a to be bent toward the side surface of the backlight unit. The second coupling unit 160c is bent toward the rear surface of the backlight unit from the connection unit 160b to be electrically coupled to the source printed circuit board.

Further, the flexible film 160 may include a driving IC 168 such as a data driver IC.

A plurality of coupling pads CP which is electrically coupled to the pad electrode of the pad unit through the conductive layer 165 is provided on the front surface of the first coupling unit 160a.

The number of coupling pads CP corresponds to the number of pad electrodes of the pad unit.

The coupling pads CP are provided so as to correspond to the pad electrodes of the pad unit one to one.

The source printed circuit board is disposed on one end of the flexible film 160 to be electrically coupled to the second coupling unit 160c of the flexible film 160.

A plurality of coupling pads (not illustrated) which is electrically coupled to the output pad of the source printed circuit board may be provided on the rear surface of the second coupling unit 160c in the same way

The number of coupling pads corresponds to the number of output pads of the source printed circuit board.

The coupling pads are provided so as to correspond to the output pads of the source printed circuit board one to one.

Hereinafter, electric coupling between the pad unit and the flexible film will be described in detail together with planar and cross-sectional structures of the display panel.

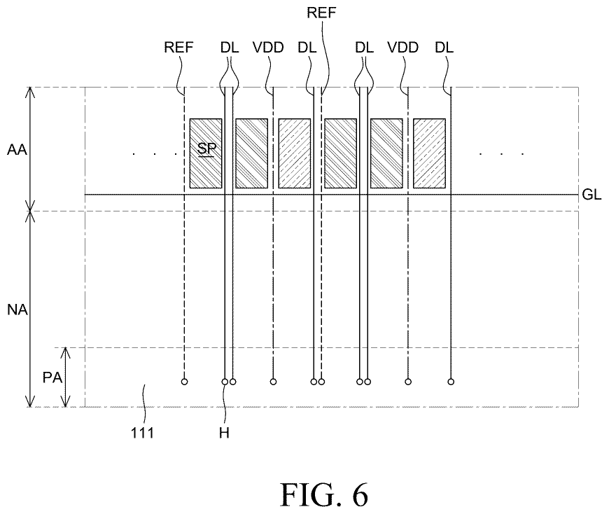

FIG. 6 is a plan view illustrating a part of a display panel according to an example embodiment of the present disclosure.

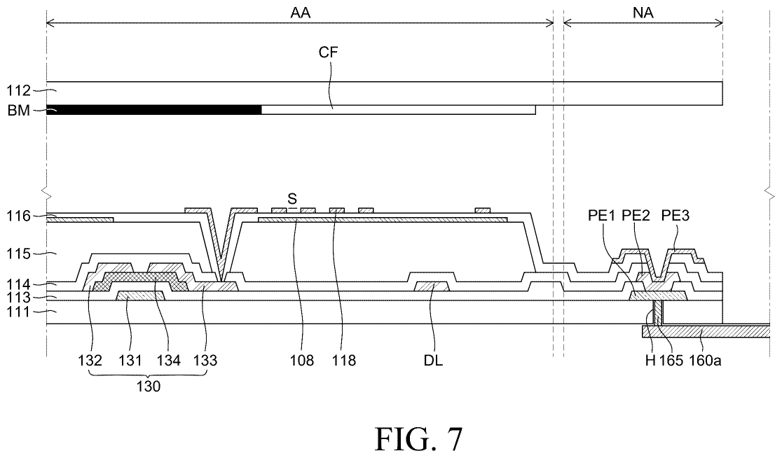

FIG. 7 is a cross-sectional view illustrating a part of a display panel according to an example embodiment of the present disclosure.

FIG. 6 illustrates a part of the planar structure of the array substrate 111 below the display panel which is coupled to the flexible film and FIG. 7 illustrates a cross-sectional structure of the display panel taken along I-I′ of FIG. 1.

FIG. 7 illustrates a fringe field switching (FFS) mode display panel as an example, but the present disclosure is not limited thereto and may also be applied to a twisted nematic (TN) or in-plane switching (IPS) mode display panel.

As shown in FIGS. 6 and 7, according to the example embodiment of the present disclosure, the display panel is divided into an active area AA and a non-active area NA in an outer periphery of the active area AA.

Between them, the active area AA is an area in which an input image is displayed, and sub pixels SP will be disposed in a matrix type. The non-active area NA includes a pad area PA in which a pad unit is disposed.

In the active area AA, a gate line GL, a data line DL, a reference line REF, and a pixel power line VDD are disposed.

The gate line GL is disposed in a first direction, for example, a horizontal direction and the data line DL, the reference line REF, and the pixel power line VDD are disposed in a second direction, for example, in a vertical direction. As described above, the gate line GL and the data line DL intersect to define a sub pixel SP.

The pixel power line VDD supplies a power to each sub pixel SP disposed in the active area AA.

The reference line REF supplies an initial voltage (or a sensing voltage) to each sub pixel SP disposed in the active area AA.

The reference line REF and the pixel power line VDD are disposed between the plurality of data lines DL.

A thin film transistor 130 is disposed in the sub pixel SP defined by the gate line GL and the data line DL.

The thin film transistor 130 is disposed above the lower substrate 111.

The lower substrate 111 may be formed of a glass or a transparent plastic. For example, the lower substrate 111 may be formed of a transparent flexible material.

The gate line GL and the gate electrode 131 are disposed on the lower substrate 111.

In the meantime, the first pad electrode PE1 is disposed above the lower substrate 111 of the non-active area NA. The first pad electrode PE1 is electrically coupled to a signal line, such a s the gate line GL or the data line DL.

The gate line GL, the gate electrode 131, and the first pad electrode PE1 may be formed of molybdenum (Mo), aluminum (Al), chrome (Cr), gold (Au), titanium (Ti), nickel (Ni), neodymium (Nd), copper (Cu), or an alloy thereof and formed by a single layer of metal or alloy thereof or two or more multiple layers.

A gate insulating film 113 is disposed above the gate line GL, the gate electrode 131, and the first pad electrode PE1.

The gate insulating film 113 is formed of an inorganic insulating material, such as silicon oxide or silicon nitride.

The semiconductor layer 134 is disposed on the gate insulating film 113.

The semiconductor layer 134 is disposed on the gate insulating film 113 while overlapping the gate electrode 131 in a thin film transistor area.

The semiconductor layer 134 is formed of a silicon based semiconductor material or is formed of an oxide semiconductor material.

The data line DL, the source electrode 132, and the drain electrode 133 are disposed above the lower substrate 111 on which the semiconductor layer 134 is disposed.

In the meantime, the second pad electrode PE2 is disposed on the gate insulating film 113 of the non-active area NA. The second pad electrode PE2 is electrically coupled to the first pad electrode PE1 through a contact hole. However, the present disclosure is not limited thereto, and the second pad electrode PE2 may be omitted.

The data line DL, the source electrode 132, the drain electrode 133, and the second pad electrode PE2 may be formed of molybdenum (Mo), aluminum (Al), chrome (Cr), gold (Au), titanium (Ti), nickel (Ni), neodymium (Nd), copper (Cu), or an alloy thereof and formed by a single layer of metal or alloy thereof or two or more multiple layers.

A first protection film 114 may be disposed above the data line DL, the source electrode 132, the drain electrode 133, and the second pad electrode PE2.

The first protection film 114 is formed of an inorganic insulating material, such as silicon oxide or silicon nitride.

A second protection film 115 is disposed on the first protection film 114 of the active area AA.

The second protection film 115 is formed of an organic insulating material, such as photoacryl. The second protection film 115 also functions to planarize the lower substrate 111.

The common electrode 108 is disposed on the second protection film 115.

The common electrodes 108 adjusts an orientation of a liquid crystal layer by forming a field together with the pixel electrode 118. The common electrode 108 is configured by a transparent electrode, such as ITO.

A third protection film 116 may be disposed above the common electrode 108.

The third protection film 116 is formed of an inorganic insulating material, such as silicon oxide or silicon nitride.

The pixel electrode 118 is disposed on the third protection film 116.

The pixel electrode 118 is configured by a transparent electrode, such as ITO.

The pixel electrode 118 includes a slit S therein so that the display device according to the present disclosure may be applied to an IPS mode liquid crystal display device or an FFS mode liquid crystal display device.

In the meantime, the third pad electrode PE3 is disposed above the third protection film 116 of the non-active area NA. The third pad electrode PE3 is electrically coupled to the second pad electrode PE2 through a contact hole. However, the present disclosure is not limited thereto, and the third pad electrode PE3 may be omitted.

The upper substrate 112 is disposed above the lower substrate 111 configured as described above.

The black matrix BM and the color filter CF are disposed on a top surface of the upper substrate 112 which is opposite to the lower substrate 111.

An overcoat layer (not illustrated) may be disposed on the upper substrate 112 on which the black matrix BM and the color filter CF are disposed.

In the meantime, a plurality of holes H which passes through the lower substrate 111 is provided on the lower substrate 111 of the non-active area NA.

The hole H is formed to pass through the lower substrate 111 of the pad area PA to expose each first pad electrode PE1.

The hole H may pass through the lower substrate 111 from the rear surface of the lower substrate 111 toward the first pad electrode PE1.

For example, a cross-sectional shape of the hole H is a circle, but is not limited thereto and may be various shapes, such as an oval or a polygon.

The number of holes H may correspond to the number of first pad electrodes PE1.

The holes H may be provided correspond to the first pad electrodes PE1 one to one.

The conductive layer 165 is disposed in the hole H.

The conductive layer 165 may be printed using metal, such as copper (Cu), but is not limited thereto.

Upper and lower portions of the hole H may be electrically conducted by the conductive layer 165.

One end of the conductive layer 165 is electrically coupled to the first pad electrode PE1 and the other end is electrically coupled to the first coupling unit 160a of the flexible film.

In the meantime, the formation position of the hole may vary by considering the interval between adjacent first pad electrodes, which will be described in detail with reference to the drawings.

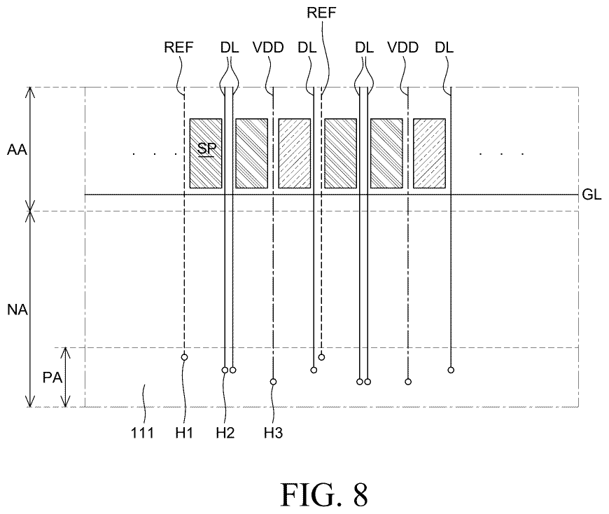

FIG. 8 is a plan view illustrating a part of a display panel according to another example embodiment of the present disclosure.

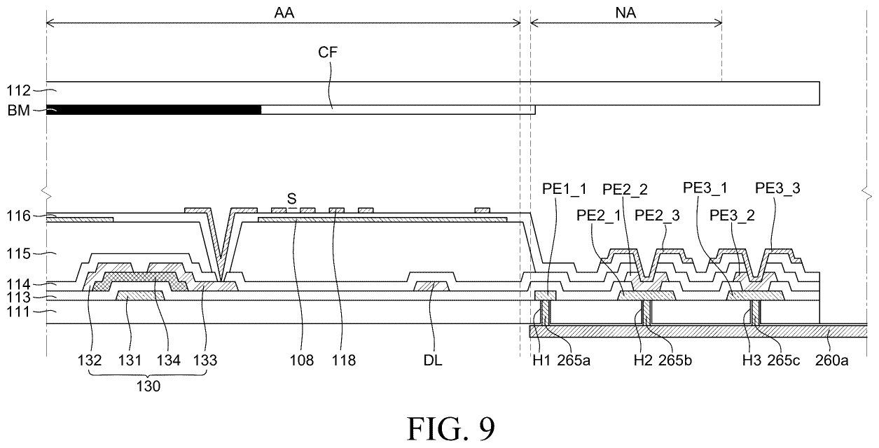

FIG. 9 is a cross-sectional view illustrating a part of a display panel according to another example embodiment of the present disclosure.

Another example embodiment of the present disclosure of FIGS. 8 and 9 is different from the example embodiment of the present disclosure of FIGS. 6 and 7 in the formation position of holes H1, H2, and H3 and a coupling relationship of a pad electrode and a flexible film thereby and the other configuration is substantially the same. Therefore, a redundant description will be omitted. The same configuration will be denoted by the same reference numeral. Here, the description for the same reference numeral may refer to FIGS. 1 to 7.

FIG. 8 illustrates a part of the planar structure of the array substrate 111 below the display panel which is coupled to the flexible film and FIG. 9 illustrates a part of a cross-sectional structure of a display panel.

As shown in FIGS. 8 and 9, according to another example embodiment of the present disclosure, the display panel is divided into an active area AA and a non-active area NA in an outer periphery of the active area AA.

In the active area AA, a signal line or a power line, such as a gate line GL, a data line DL, a reference line REF, and a pixel power line VDD, is disposed.

The signal line or the power line, such as a gate line GL, a data line DL, a reference line REF, and a pixel power line VDD extends to the pad area PA of the non-active area NA to be coupled to the flexible film.

According to another example embodiment of the present disclosure, the gate line GL, the data line DL, the reference line REF, and the pixel power line VDD which extend to the pad area PA include a plurality of holes H1, H2, and H3 to be coupled to the flexible film, in different positions. For example, in the plan view, the plurality of holes H1, H2, and H3 are disposed with different intervals from an edge of the active area AA.

A plurality of holes H1, H2, and H3 which passes through the lower substrate 111 is provided on the lower substrate 111 of the non-active area NA. In FIG. 8, it is illustrated that the extending reference line REF corresponds to the first hole H1, the extending data line DL corresponds to the second hole H2, and the extending pixel power line VDD corresponds to the third hole H3 as an example, but the present disclosure is not limited thereto.

At this time, the first hole H1, the second hole H2, and the third hole H3 are disposed in different columns in the pad area PA. Further, for example, in the plan view, the first hole H1, the second hole H2, and the third hole H3 are disposed in this order from an edge of the active area AA, but it is not limited thereto.

For example, a cross-sectional shape of the holes H1, H2, and H3 is a circle, but is not limited thereto and may be various shapes, such as an oval or a polygon.

Each hole H1, H2, H3 is formed to pass through the lower substrate 111 of the pad area PA to expose each first pad electrode PE1_1, PE2_1, PE3_1.

For example, in the plan view, the first pad electrodes PE1_1, PE2_1 and PE3_1 are disposed with different intervals from an edge of the active area AA.

To this end, the plurality of first pad electrodes PE1_1, PE2_1, and PE3_1 is disposed above the lower substrate 111 of the non-active area NA.

For example, the plurality of first pad electrodes PE1_1, PE2_1, and PE3_1 includes a 1-1-th pad electrode PE1_1, a 2-1-th pad electrode PE2_1, and a 3-1-th pad electrode PE3_1 in the order adjacent to the active area AA.

At this time, the 1-1-th pad electrode PE1_1, the 2-1-th pad electrode PE2_1, and the 3-1-th pad electrode PE3_1 are disposed in different columns in the pad area PA. Further, for example, in the plan view, the 1-1-th pad electrode PE1_1, the 2-1-th pad electrode PE2_1, and the 3-1-th pad electrode PE3_1 are disposed in this order from the edge of the active area AA, but the present disclosure is not limited thereto.

Further, for example, the 1-1-th pad electrode PE1_1 is electrically coupled to any one of the gate line GL, the data line DL, the reference line REF, and the pixel power line VDD.

Further, the 2-1-th pad electrode PE2_1 is electrically coupled to another one of the gate line GL, the data line DL, the reference line REF, and the pixel power line VDD.

Further, the 3-1-th pad electrode PE3_1 is electrically coupled to the third one of the gate line GL, the data line DL, the reference line REF, and the pixel power line VDD.

Each hole H1, H2, H3 may pass through the lower substrate 111 from the rear surface of the lower substrate 111 toward each first pad electrode PE1_1, PE2_1, PE3_1.

For example, the number of individual holes H1, H2, H3 corresponds to the number of each of the first pad electrodes PE1_1, PE2_1, and PE3_1. Further, each hole H1, H2, H3 is provided so as to corresponds to the first pad electrode PE1_1, PE2_1, PE3_1 one to one.

For example, the first pad electrode PE1_1, PE2_1, PE3_1 may be disposed on the same layer as the gate line GL and the gate electrode 131, but the present disclosure is not limited thereto.

The gate insulating film 113 is disposed above the first pad electrodes PE1_1, PE2_1, and PE3_1.

A plurality of second pad electrodes PE2_2 and PE3_2 is disposed on the gate insulating film 113 of the non-active area NA.

For example, the plurality of second pad electrodes PE2_2 and PE3_2 includes a 2-2-th pad electrode PE2_2 which is electrically coupled to a 2-1-th pad electrode PE2_1 through a contact hole and a 3-2-th pad electrode PE3_2 which is electrically coupled to the 3-1-th pad electrode PE3_1 through a contact hole. However, the present disclosure is not limited thereto, and the 2-2-th pad electrode PE2_2 and/or the 3-2-th pad electrode PE3_2 may be omitted.

The second pad electrodes PE2_2 and PE3_2 are disposed on the same layer as the data line DL, the source electrode 132, and the drain electrode 133, but the present disclosure is not limited thereto.

The first protection film 114 and the third protection film 116 are disposed above the second pad electrodes PE2_2 and PE3_2.

A plurality of third pad electrodes PE2_3 and PE3_3 is disposed above the third protection film 116 of the non-active area NA.

For example, the plurality of third pad electrodes PE2_3 and PE3_3 includes a 2-3-th pad electrode PE2_3 which is electrically coupled to a 2-2-th pad electrode PE2_2 through a contact hole and a 3-3-th pad electrode PE3_3 which is electrically coupled to the 3-2-th pad electrode PE3_2 through a contact hole. However, the present disclosure is not limited thereto, and the 2-3-th pad electrode PE2_3 and/or the 3-3-th pad electrode PE3_3 may be omitted.

The third pad electrodes PE2_3 and PE3_3 are disposed on the same layer as the pixel electrode 118, but are not limited thereto.

The upper substrate 112 is disposed above the lower substrate 111 configured as described above.

In the meantime, conductive layers 265a, 265b, and 265c are disposed in the holes H1, H2, and H3.

The conductive layers 265a, 265b, and 265c may be printed using metal, such as copper (Cu), but are not limited thereto.

Upper and lower portions of each hole H1, H2, H3 are electrically conducted by each conductive layers 265a, 265b, 265c.

One ends of the conductive layers 265a, 265b, and 265c are electrically coupled to the first pad electrodes PE1_1, PE2_1, and PE3_1 and the other ends is electrically coupled to the first coupling unit 260a of the flexible film.

At this time, for example, the conductive layers 265a, 265b, and 265c include a first conductive layer 265a, a second conductive layer 265b, and a third conductive layer 265c. One end of the first conductive layer 265 a is electrically coupled to the 1-1-th pad electrode PE1_1 and the other end is electrically coupled to the first coupling unit 260a of the flexible film. Further, one end of the second conductive layer 265 b is electrically coupled to the 2-1-th pad electrode PE2_1 and the other end is electrically coupled to the first coupling unit 260a of the flexible film. Further, one end of the third conductive layer 265 c is electrically coupled to the 3-1-th pad electrode PE3_1 and the other end is electrically coupled to the first coupling unit 260a of the flexible film. Even though it is not illustrated in detail, the first coupling unit 260a of the flexible film includes a plurality of coupling pads (CP in FIG. 5) each electrically coupled to each of the conductive layers 265a, 265b, and 265c.

For example, in the plan view, the first conductive layer 265a, the second conductive layer 265b, and the third conductive layer 265c are disposed in this order from the edge of the active area AA, but the present disclosure is not limited thereto.

As described above, according to another example embodiment of the present disclosure, the holes H1, H2, and H3 which are coupled to the flexible film are formed in different positions in the pad area PA in the plan view. Therefore, when the first pad electrodes PE1_1, PE2_1, and PE3_1 and the conductive layers 265a, 265b, and 265c are coupled, it is advantageous in that interruption or short-circuit between the wiring lines is suppressed and a degree of freedom of design of the wiring line is increased.

The example embodiments of the present disclosure can also be described as follows:

According to an aspect of the present disclosure, there is provided a display device. The display device includes a lower substrate having a thin film transistor disposed thereon, an upper substrate disposed above the lower substrate, a plurality of pad electrodes disposed in a non-active area of the lower substrate, a hole extending through the lower substrate from a lower surface of the lower substrate toward a pad electrode, among the plurality of pad electrodes, and a flexible film coupled to the pad electrode through a conductive layer disposed in the hole.

The display device may further include a liquid crystal layer disposed between the lower substrate and the upper substrate.

The lower substrate and the upper substrate may configure a display panel, and the display device may further include a backlight unit disposed on a rear surface of the display panel and a source printed circuit board disposed on a rear surface of the backlight unit and electrically coupled to the flexible film.

The flexible film may include a first coupling unit disposed on a rear surface of the lower substrate and electrically coupled to the pad electrode through the conductive layer, a connection unit extending from the first coupling unit and bent toward a side surface of the backlight unit and a second coupling unit bent toward a rear surface of the backlight unit from the connection unit and electrically coupled to the source printed circuit board.

The source printed circuit board may be mounted on one end of the flexible film to be electrically coupled to the second coupling unit.

The display device may further include a bottom cover which houses the backlight unit, and the bottom cover may include, a lower portion disposed on a rear surface of the backlight unit to support the backlight unit and a side portion bent vertically from an edge of the lower portion.

The display device may further include a plurality of holes, including the hole, extending through the lower substrate from the lower surface of the lower substrate respectively toward the plurality of pad electrodes. The number of holes may correspond to the number of pad electrodes.

One end of the conductive layer may be electrically coupled to the pad electrode and the other end may be electrically coupled to the first coupling unit.

The display device may further comprise a plurality of coupling pads disposed on a front surface of the first coupling unit and electrically coupled to the pad electrode through the conductive layer,

The number of coupling pads may correspond to the number of pad electrodes.

The display device may further comprise a plurality of coupling pads disposed on a rear surface of the second coupling unit and electrically coupled to an output pad of the source printed circuit board.

The number of coupling pads may correspond to the number of output pads of the source printed circuit board.

According to another aspect of the present disclosure, there is provided a display device. The display device includes a lower substrate having a thin film transistor disposed thereon, an upper substrate disposed above the lower substrate, a plurality of wiring lines disposed in an active area of the lower substrate and applying a signal or a voltage to the thin film transistor, a plurality of pad electrodes disposed in a pad area of the lower substrate and electrically coupled to the plurality of wiring lines, a plurality of holes extending through the lower substrate from a lower surface of the lower substrate toward the plurality of pad electrodes, respectively, and a flexible film coupled to a pad electrode, among the plurality of pad electrodes, through a conductive layer disposed in a corresponding one of the plurality of holes, the flexible film may be disposed on a rear surface of the lower substrate so as not to be visible from an upper portion of the lower substrate.

In the plan view, the plurality of pad electrodes and the plurality of holes may be disposed at different distances from an edge of the active area.

The lower substrate and the upper substrate may configure a display panel, and the display device may further include a backlight unit disposed on a rear surface of the display panel and a source printed circuit board disposed on a rear surface of the backlight unit and electrically coupled to the flexible film.

The flexible film may include a first coupling unit disposed on a rear surface of the lower substrate and electrically coupled to the pad electrode through the conductive layer, a connection unit extending from the first coupling unit and bent toward a side surface of the backlight unit and a second coupling unit bent toward a rear surface of the backlight unit from the connection unit and electrically coupled to the source printed circuit board.

The source printed circuit board may be mounted on one end of the flexible film and electrically coupled to the second coupling unit.

One end of the conductive layer may be electrically coupled to the pad electrode and the other end is electrically coupled to the first coupling unit.

Although the example embodiments of the present disclosure have been described above in detail with reference to the accompanying drawings, the present disclosure is not limited thereto and may be embodied in many different forms without departing from the technical concept of the present disclosure. Therefore, the example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a lower substrate having a thin film transistor disposed thereon;
an upper substrate disposed above the lower substrate;
a plurality of pad electrodes disposed in a non-active area of the lower substrate;
a hole extending through the lower substrate from a lower surface of the lower substrate toward a pad electrode among the plurality of pad electrodes; and
a flexible film coupled to the pad electrode through a conductive layer disposed in the hole.

2. The display device according to claim 1, further comprising:
a liquid crystal layer disposed between the lower substrate and the upper substrate.

3. The display device according to claim 1, wherein the lower substrate and the upper substrate configure a display panel, and
wherein the display device further comprises:
a backlight unit disposed on a rear surface of the display panel; and
a source printed circuit board disposed on a rear surface of the backlight unit and electrically coupled to the flexible film.

4. The display device according to claim 3, wherein the flexible film includes:
a first coupling unit disposed on a rear surface of the lower substrate and electrically coupled to the pad electrode through the conductive layer;
a connection unit extending from the first coupling unit and bent toward a side surface of the backlight unit; and
a second coupling unit bent toward a rear surface of the backlight unit from the connection unit and electrically coupled to the source printed circuit board.

5. The display device according to claim 4, wherein the source printed circuit board is mounted on one end of the flexible film to be electrically coupled to the second coupling unit.

6. The display device according to claim 3, further comprising:
a bottom cover which houses the backlight unit, and
wherein the bottom cover includes:
a lower portion disposed on a rear surface of the backlight unit to support the backlight unit; and
a side portion bent vertically from an edge of the lower portion.

7. The display device according to claim 1, further comprising:
a plurality of holes, including the hole, extending through the lower substrate from the lower surface of the lower substrate respectively toward the plurality of pad electrodes,
wherein the number of holes corresponds to the number of pad electrodes.

8. The display device according to claim 4, wherein one end of the conductive layer is electrically coupled to the pad electrode and the other end is electrically coupled to the first coupling unit.

9. The display device according to claim 4, further comprising:
a plurality of coupling pads disposed on a front surface of the first coupling unit and electrically coupled to the pad electrode through the conductive layer.

10. The display device according to claim 9, wherein the number of coupling pads corresponds to the number of pad electrodes.

11. The display device according to claim 4, further comprising:
a plurality of coupling pads disposed on a rear surface of the second coupling unit and electrically coupled to an output pad of the source printed circuit board.

12. The display device according to claim 11, wherein the number of coupling pads corresponds to the number of output pads of the source printed circuit board.

13. A display device, comprising:
a lower substrate having a thin film transistor disposed thereon;
an upper substrate disposed above the lower substrate;
a plurality of wiring lines disposed in an active area of the lower substrate and applying a signal or a voltage to the thin film transistor;
a plurality of pad electrodes disposed in a pad area of the lower substrate and electrically coupled to the plurality of wiring lines;
a plurality of holes extending through the lower substrate from a lower surface of the lower substrate toward the plurality of pad electrodes, respectively; and
a flexible film coupled to a pad electrode, among the plurality of pad electrodes, through a conductive layer disposed in a corresponding one of the plurality of holes,
wherein the flexible film is disposed on a rear surface of the lower substrate so as not to be visible from an upper portion of the lower substrate.

14. The display device according to claim 13, wherein in a plan view, the plurality of pad electrodes and the plurality of holes are disposed at different distances from an edge of the active area.

15. The display device according to claim 13, wherein the lower substrate and the upper substrate configure a display panel, and
wherein the display device further comprises:
a backlight unit disposed on a rear surface of the display panel; and
a source printed circuit board disposed on a rear surface of the backlight unit and electrically coupled to the flexible film.

16. The display device according to claim 15, wherein the flexible film includes:
a first coupling unit disposed on a rear surface of the lower substrate and electrically coupled to the pad electrode through the conductive layer;
a connection unit extending from the first coupling unit and bent toward a side surface of the backlight unit; and
a second coupling unit bent toward a rear surface of the backlight unit from the connection unit and electrically coupled to the source printed circuit board.

17. The display device according to claim 16, wherein the source printed circuit board is mounted on one end of the flexible film and electrically coupled to the second coupling unit.

18. The display device according to claim 16, wherein one end of the conductive layer is electrically coupled to the pad electrode and the other end is electrically coupled to the first coupling unit.
